(19) United States
(12) Patent Application Publication
(10) Pub. No.: US 2022/0392935 A1
(43) Pub. Date: Dec. 8, 2022

(54) IMAGE SENSOR AND MANUFACTURING METHOD THEREOF

(71) Applicant: Silicon Optronics, Inc., Hsinchu (TW)

(72) Inventor: Bo-Ray LEE, Hsinchu (TW)

(21) Appl. No.: 17/397,106

(22) Filed: Aug. 9, 2021

(30) Foreign Application Priority Data
Jun. 2, 2021 (TW) 110119965

(51) Int. Cl. H01L 27/146

(52) U.S. Cl. CPC H01L 27/14623; H01L 27/14643; H01L 27/14621; H01L 27/14625; H01L 27/14627; H01L 27/1463; H01L 27/14685; H01L 27/14689

(57) ABSTRACT

An image sensor is provided. The image sensor includes a substrate, a photodiode, and a storage node. The photodiode is disposed in the substrate and close to a first end of the substrate. The storage node is disposed in the substrate, adjacent to the photodiode, and close to the first end of the substrate. The image sensor further includes a first isolation structure, a first light shielding structure, an interlayer dielectric layer, and a lens structure. The first isolation structure is disposed in the substrate and over the storage node. The first light shielding structure is disposed in the first isolation structure. The interlayer dielectric layer is disposed over a second end of the substrate. The second end is opposite the first end. The lens structure is disposed over the interlayer dielectric layer.

### CROSS REFERENCE TO RELATED APPLICATIONS

This application claims priority of Taiwan Patent Application No. 110119965, filed on Jun. 2, 2021, the entirety of which is incorporated by reference herein.

### BACKGROUND OF THE INVENTION

### Field of the Invention

The present invention relates to an image sensor, and, in particular, to an image sensor with an isolation structure.

### Description of the Related Art

In general, a complementary metal oxide semiconductor (CMOS) image sensor is composed of active pixels and periphery circuits. The functions of active pixels include photon collection, photon-electron transformation, electron collection, and outputting voltage through a source follower. The peripheral circuit performs signal processing.

Conventional CMOS image sensors use rolling shutters. However, for high-speed moving objects, the CMOS image sensors using the rolling shutters may suffer from image distortion. Therefore, global shutters are developed to solve this problem. The pixels of the global shutters will be exposed at the same time and the signal will be stored in storage nodes (SN). Accordingly, an undistorted image of a high-speed object can be obtained.

However, when the CMOS image sensors are irradiated by light with high light intensity, the light leaking to the storage nodes cannot be ignored, because the signal caused by the light leaking to the storage nodes is comparable to the signal converted by photodiodes (PD) of pixels, and thus the storage nodes will be interfered. This issue is called parasitic light sensitivity (PLS) or global shutter efficiency (GSE). Therefore, a new image sensor structure is needed to solve this issue.

### BRIEF SUMMARY OF THE INVENTION

An embodiment of the present invention provides an image sensor. The image sensor comprises a substrate, a photodiode, a storage node, and a first isolation structure. The photodiode is disposed in the substrate and close to a first end of the substrate. The storage node is disposed in the substrate, adjacent to the photodiode, and close to the first end of the substrate. The first isolation structure is disposed in the substrate and over the storage node. The image sensor further comprises a first light shielding structure, an interlayer dielectric layer, and a lens structure. The first light shielding structure is disposed in the first isolation structure. The interlayer dielectric layer is disposed over a second end of the substrate. The second end is opposite the first end. The lens structure is disposed over the interlayer dielectric layer.

An embodiment of the present invention provides a method for manufacturing an image sensor. The method comprises providing a semiconductor structure, wherein the semiconductor structure comprises a substrate and an intermetal dielectric layer below the first end of the substrate, and wherein the substrate comprises a photodiode close to the first end and a storage node close to the first end and adjacent to the photodiode. The method further comprises forming a first trench in the substrate from the second end of the substrate, wherein the second end is opposite the first end, and wherein the first trench is over the storage node; forming a first isolation structure in the first trench; forming a second trench in the first isolation structure; and forming a first light shielding structure in the second trench.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1 to 8 illustrate cross-sectional views of a portion of an image sensor, in accordance with some embodiments of the present disclosure.

FIGS. 9 to 16 illustrate cross-sectional views of intermediate stages for forming a portion of the image sensor, in accordance % with some embodiments of the present disclosure.

### DETAILED DESCRIPTION OF THE INVENTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the present disclosure is not limited by the illustrated ordering of acts or events, as some acts may occur in different orders and/or concurrently with other acts or events. Furthermore, not all illustrated acts or events are required to implement a methodology in accordance with the present disclosure.

The CMOS image sensors are generally classified into frontside illumination (FSI) image sensors and backside illumination (BSI) image sensors. For FSI image sensors, the incident light must pass through the intermetal dielectric (IMD) layer and the interconnection structure therein before reaching the photodiodes in the substrate. On the other hand, the intermetal dielectric layers of BSI image sensors are disposed on the other side of the substrate. Therefore, for the BSI image sensors, light does not pass through the intermetal dielectric layer and the interconnection structure therein. The embodiments and drawings provided in the present disclosure all use BSI image sensors as examples, but it should be noted that, the inventive concept of the present disclosure can also be applied to FSI image sensors.

In general, the pixels of an image sensor using a global shutter include photodiodes, transfer gates, storage nodes, global transfer gates, floating diffusion (FD) elements, reset transistors, source followers, etc. The electrons converted by the photodiodes are transferred to the storage nodes through the transfer gates disposed between the photodiodes and the storage nodes, wherein the storage nodes may be photodiodes or capacitor structures. Then, the electrons in the storage nodes can be transferred to the floating diffusion elements through the global transfer gates disposed between the storage nodes and the floating diffusion elements, wherein the floating diffusion elements may be capacitor structures. Afterwards, the floating diffusion elements can be read by the source followers to create the image sensed by the image sensor. The reset transistors may be used to reset the pixels.

However, as described above, the light leaking to the storage nodes may interfere the storage nodes. For example, in the regions of the substrate corresponding to the photodiodes, the electrons converted from the photons may diffuse to the storage nodes and cause electrical crosstalk, alternatively, the light being directly incident to the storage nodes may cause optical crosstalk. In order to solve these crosstalk issues, various embodiments of the present disclosure provide a novel CMOS image sensor structure to suppress the electrical crosstalk and optical crosstalk described above, and improve the performance of the CMOS image sensor.

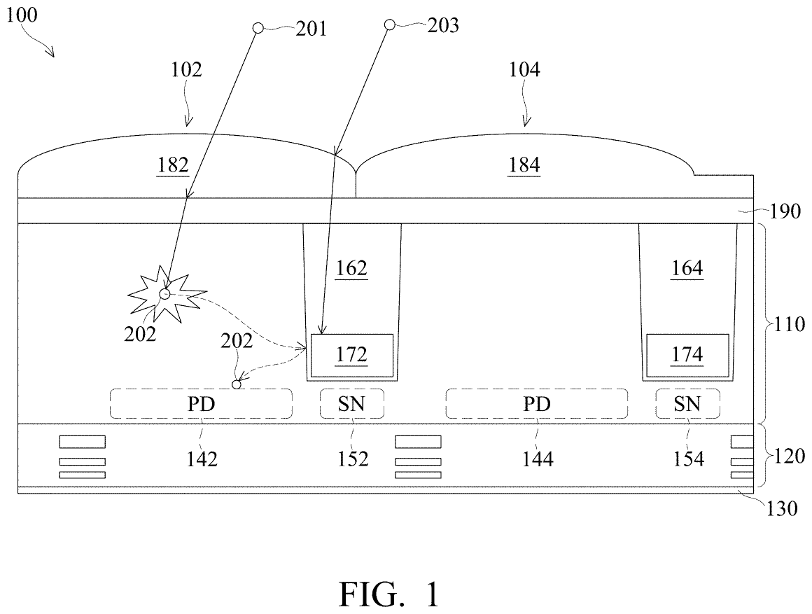

FIG. 1 illustrates a cross-sectional view of a portion of an image sensor, in accordance with some embodiments of the present disclosure. In the embodiment illustrated in FIG. 1, a semiconductor structure 100 includes a first pixel 102 and second pixel 104 formed in/on a substrate 110, an intermetal dielectric (IMD) layer, and a passivation layer 130. The first pixel 102 includes a photodiode 142, a storage node 152, an isolation structure 162, a light shielding structure 172, and a lens structure 182. The second pixel 104 includes a photodiode 144, a storage node 154, an isolation structure 164, a light shielding structure 174, and a lens structure 184. In some embodiments, the first pixel 102 and the second pixel 104 further include an interlayer dielectric (ILD) layer 190 between the substrate 110 (and/or the isolation structures 162 and 164) and lens structures 182 and 184.

It should be noted that, for the purpose of simplicity, some elements are omitted in the drawings herein. For example, the intermetal dielectric layer 120 may comprise interconnect structures (including metal lines and vias, etc.) having multiple metal layers and various elements, such as transfer gates, global transfer gates, reset transistors, source followers, etc. In addition, floating diffusion elements may be disposed in the substrate 110.

The photodiode 142 and the storage node 152 are disposed in the substrate 110 and are adjacent to each other. The photodiode 144 and the storage node 154 are disposed in the substrate 110 and are adjacent to each other. As shown in FIG. 1, the photodiodes 142, 144 and the storage nodes 152, 154 are close to the first end of the substrate 110. In FIG. 1, the first end is shown as the “bottom” of the substrate 110 and is adjacent to the underlying intermetal dielectric layer 120.

As described above, the drawings of the present disclosure do not illustrate elements such as transfer gates, global transfer gates, floating diffusion elements, etc. In some embodiments, the floating diffusion elements may be disposed in the substrate 110, and located on the side of the storage node 152 away from the photodiode 142 and the side of the storage node 154 away from the photodiode 144. The transfer gates may be disposed in the intermetal dielectric layer 120 and located between the photodiode 142 (or photodiode 144) and the storage node 152 (or storage node 154). The global transfer gates may be disposed in the intermetal dielectric layer 120 and located between the storage node 152 (or storage node 154) and the floating diffusion elements.

The substrate 110 may be a semiconductor substrate, such as a silicon substrate. In addition, the material of the semiconductor substrate may be another elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide (InSb); an alloy semiconductor, such as silicon germanium (SiGe), GaAsP, AlInAs, AlGaAs, GaInAs, GaInP, and/or GaInAsP; or combinations thereof. Furthermore, the substrate 110 may also be a semiconductor-on-insulator (SOI) substrate.

The intermetal dielectric layer 120 may include one or more dielectric materials, such as SiO₂, Si₃N₄, SiN, SiON, SiOC, SiOCN, tetraethylorthosilicate (TEOS) formed oxide, un-doped silicate glass (USG), or doped silicon oxide such as borophosphosilicate glass (BPSG), fluorosilicate glass (FSG), phosphosilicate glass (PSG), boron doped silicon glass (BSG), other suitable dielectric materials, and combinations thereof. The passivation layer 130 may include AlN, Al₂O₃. AON, SiN, SiO₂, SiON. Si₃N₄, or combinations thereof.

Still referring to FIG. 1, the first pixel 102 comprises the isolation structure 162 disposed in the substrate 110, wherein the isolation structure 162 is located over the storage node 152. The second pixel 104 comprises the isolation structure 164 disposed in the substrate 110, wherein the isolation structure 164 is located over the storage node 154. In some embodiments, from a top view, the isolation structure 162 and the isolation structure 164 completely cover the storage node 152 and the storage node 154, respectively. The first pixel 102 further comprises the light shielding structure 172 disposed in the isolation structure 162 and located over the storage node 152. The second pixel 104 further comprises the light shielding structure 174 disposed in the isolation structure 164 and located over the storage node 154.

With the isolation structure 162, the electrons excited by the photons incident to the region of the substrate 110 corresponding to the photodiode 142 will be blocked by the isolation structure 162 and cannot diffuse to the storage node 152. As shown in FIG. 1, a photon 201 is incident to the substrate 110 and excites an electron 202, and then the electron 202 diffuses toward the storage node 152. However, the electron 202 is blocked by the isolation structure 162 and cannot enter the storage node 152. Similarly, the electrons excited by photons will be blocked by the isolation structure 164 and cannot diffuse to the storage node 154. As a result, the electrical crosstalk of the image sensor can be reduced, and the performance degradation caused by parasitic light sensitivity can be reduced.

On the other hand, the light shielding structure 172 can prevent photons from being directly incident to the storage node 152. As shown in FIG. 1, a photon 203 incident toward the storage node 152 is blocked by the light shielding structure 172, and thus the photon 203 cannot enter the storage node 152. Similarly, the light shielding structure 174 can prevent photons from being directly incident to the storage node 154. As a result, the optical crosstalk of the image sensor can be reduced, and the performance degradation caused by parasitic light sensitivity can be reduced.

As described above, the isolation structure (e.g. isolation structures 162 and 164) provided by the embodiment of the present disclosure can effectively reduce electrical crosstalk. Moreover, the light shielding structure (e.g. the light shielding structures 172 and 174) provided by the embodiment of the present disclosure can effectively reduce the optical crosstalk. As a result, the performance degradation caused by parasitic light sensitivity can be dramatically suppressed, and thus the performance of the image sensor can be improved.

In some embodiments, the isolation structures 162 and 164 are deep trench isolation (DTI) structures. The isolation structures 162 and 164 may include one or more dielectric materials, such as SiO₂, Si₃N₄, SiN, SiON, SiOC, SiOCN, Al₂O₃, MgO, Sc₂O₃, HfO2, HfSiO, HfSiON, HfTaO, HfTiO, HfZrO, LaO, ZrO, TiO₂, ZnO₂, ZrO₂, AlSiN₃, SiC, Ta₂O₅, TEOS formed oxide, USG, BPSG, FSG, PSG, BSG, other suitable dielectric materials, or combinations thereof. In some embodiments, the isolation structures 162 and 164 are made of low refractive index dielectric materials (e.g. dielectric materials with a refractive index less than about 1.46), such as carbon doped oxide, SiCOH, other suitable low refractive index materials, or combinations thereof. In these embodiments, the isolation structures 162 and 164 are more capable of reflecting electrons, thus making it more difficult for the electrons to diffuse to the storage nodes.

The light shielding structures 172 and 174 may include materials with high extinction coefficient, such as silicon nitride, tungsten nitride, metals, metal nitrides, metal oxides, inks (e.g. black ink or other suitable non-transparent inks), molding compounds (e.g. black molding compound or other suitable non-transparent molding compounds), solder masks (e.g. black solder mask or other suitable non-transparent solder masks), epoxy resin, other suitable materials, or combinations thereof.

Still referring to FIG. 1, the first pixel 102 and the second pixel 104 include an interlayer dielectric layer 190, and include the lens structure 182 and the lens structure 184, respectively. The interlayer dielectric layer 190 is disposed between the substrate 110 (and the isolation structures 162, 164) and the lens structures 182, 184. The interlayer dielectric layer 190 may include the same or similar materials as the intermetal dielectric layer 120, and for the purpose of simplicity, it will not be repeated herein.

The lens structures 182 and 184 may be micro lenses and are disposed over the interlayer dielectric layer 190. In some embodiments, the centers of the lens structures 182 and 184 may be aligned with the centers of the photodiodes 142 and 144, respectively. As a result, the lens structures 182 and 184 can condense the light to the photodiodes 142 and 144 more reliably. The material of the lens structures 182 and 184 may be light-transmitting materials, such as quartz, fused silica, gallium phosphide, calcium fluoride, silicon, optical glass, transparent plastic, other suitable materials, or combinations thereof. The lens structures 182 and 184 may be formed by photoresist thermal reflow, laser writing, gray mask, non-contact compression molding, other suitable methods, or combinations thereof.

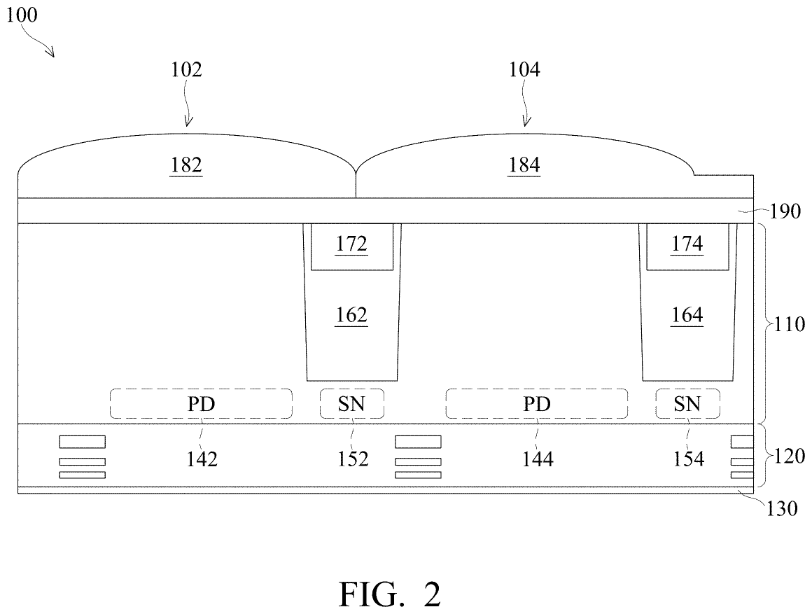

FIG. 2 illustrates a cross-sectional view of a portion of the image sensor, in accordance with some embodiments of the present disclosure. It should be noted that, since some features in FIG. 2 are the same as or similar to those in FIG. 1, the same reference signs are used for labeling these features herein. FIG. 2 has the same features as FIG. 1. In particular, FIG. 2 also has isolation structures 162, 164 and light shielding structures 172, 174.

Compared with FIG. 1, the light shielding structures 172 and 174 in FIG. 2 are located in different positions. As shown in FIG. 1, the light shielding structures 172 and 174 are located in the positions within the isolation structures 162 and 164 close to the storage nodes 152 and 154. In other words, in FIG. 1, the light shielding structures 172 and 174 are close to the first end of the substrate, that is, close to the intermetal dielectric layer 120. On the other hand, as shown in FIG. 2, the light shielding structures 172 and 174 are located in the positions within the isolation structures 162 and 164 far away from the storage nodes 152 and 154. In other words, in FIG. 2, the light shielding structures 172 and 174 are close to the second end of the substrate, wherein the second end is shown as the “top” of the substrate 110 in FIG. 2 and adjacent to the overlying interlayer dielectric layer 190.

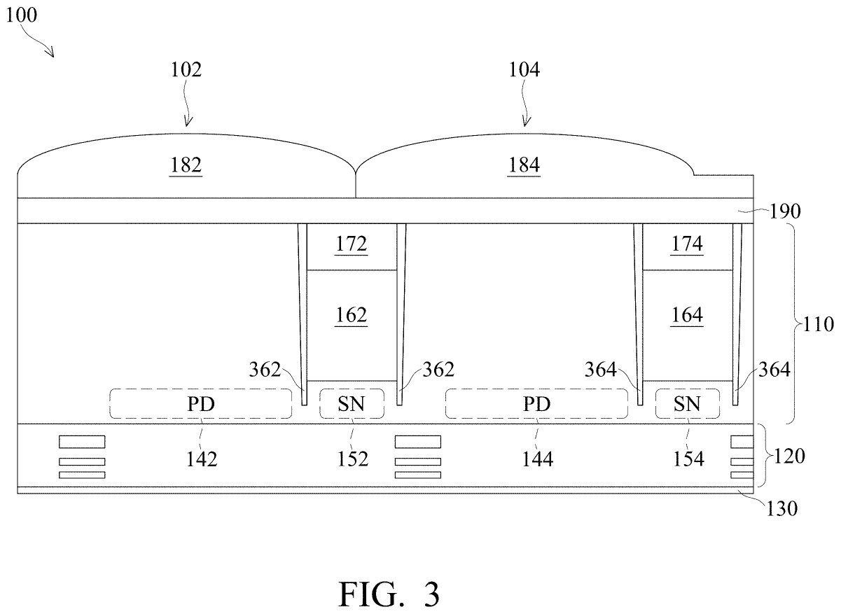

FIG. 3 illustrates a cross-sectional view of a portion of the image sensor, in accordance with some embodiments of the present disclosure. It should be noted that, since some features in FIG. 3 are the same as or similar to those in FIG. 2, the same reference signs are used for labeling these features herein.

In FIG. 3, the first pixel 102 further comprises an isolation structure 362, and the second pixel 104 further comprises an isolation structure 364. The isolation structure 362 is disposed in the substrate 110 and connected with the isolation structure 162. The isolation structure 362 surrounds the isolation structure 162 and partially surrounds the storage node 152. The isolation structure 364 is disposed in the substrate 110 and connected with the isolation structure 164. The isolation structure 364 surrounds the isolation structure 164 and partially surrounds the storage node 154. In some embodiments, the isolation structure 362 may be a portion of the isolation structure 162, and the isolation structure 364 may be a portion of the isolation structure 164. The isolation structures 362 and 364 may include the same or similar materials as the isolation structures 162 and 164, and for the purpose of simplicity, it will not be repeated herein.

Compared with the isolation structures 162 and 164, the isolation structures 362 and 364 penetrate deeper into the substrate 110 and partially surround the storage nodes 152 and 154. Therefore, the semiconductor structure 100 having the second set of isolation structures (e.g. the isolation structures 362 and 364) can more effectively prevent electrons from diffusing into the storage nodes (e.g. the storage nodes 152 and 154). As a result, the electrical crosstalk can be further reduced and the performance of the image sensor can be improved.

In some embodiments, the isolation structures 362 and 364 do not surround the isolation structures 162 and 164. In these embodiments, the isolation structures 362 and 364 only surround the storage nodes 152 and 154.

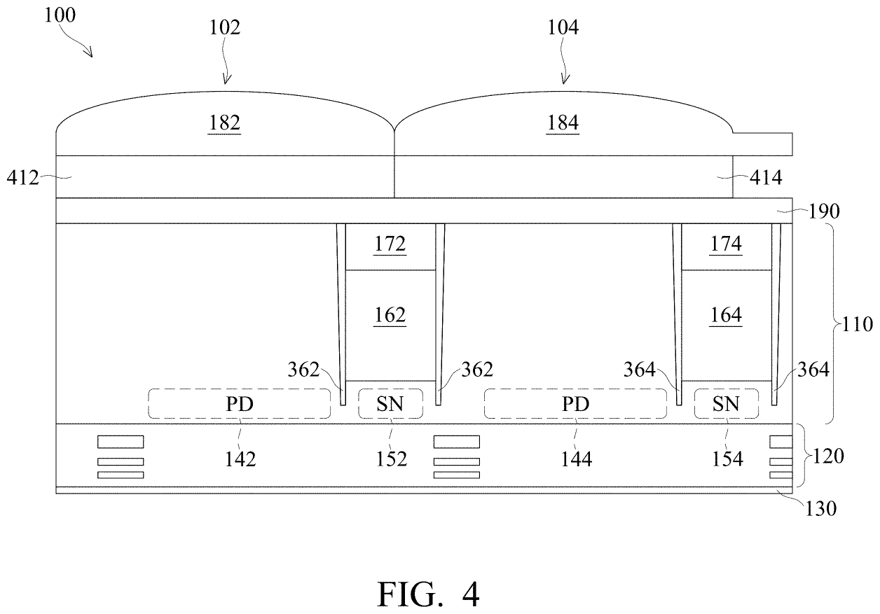

FIG. 4 illustrates a cross-sectional view of a portion of the image sensor, in accordance with some embodiments of the present disclosure. It should be noted that, since some features in FIG. 4 are the same as or similar to those in FIG. 3, the same reference signs are used for labeling these features herein.

In the embodiment illustrated in FIG. 4, the first pixel 102 further comprises a color filter 412 disposed between the interlayer dielectric layer 190 and the lens structure 182, and the second pixel 104 further comprises a color filter 414 disposed between the interlayer dielectric layer 190 and the lens structure 184. The color filters 412 and 414 are formed of materials that allow transmission of the radiation having a specific wavelength range (e.g. light), while blocking the radiation outside the specific wavelength range.

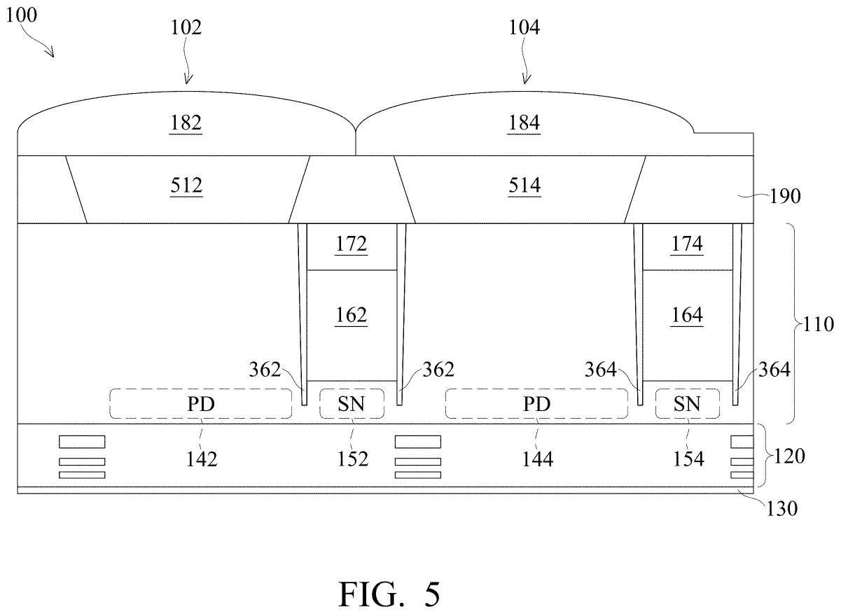

FIG. 5 illustrates a cross-sectional view of a portion of the image sensor, in accordance with some embodiments of the present disclosure. It should be noted that, since some features in FIG. 5 are the same as or similar to those in FIG. 3, the same reference signs are used for labeling these features herein. In the embodiment illustrated in FIG. 5, the first pixel 102 further comprises a light pipe 512 disposed in the interlaver dielectric layer 190 and between the substrate 110 and the lens structure 182, and the second pixel 104 further comprises a light pipe 514 disposed in the interlayer dielectric layer 190 and between the substrate 110 and the lens structure 184.

The light pipes (e.g. the light pipes 512 and 514) are configured to form total reflection for assisting lens structures (e.g., lens structures 182 and 184) to concentrate incident light on photodiodes (e.g. the photodiodes 142 and 144). The light pipes 512 and 514 may include high refractive index materials, such as polymethyl methacrylate (PMMA), perfluorocyclobutyl (PFCB) polymer, polyimide, epoxy resin, other suitable materials, or combinations thereof. In some embodiments, the refractive index of the light pipes 512 and 514 is higher than the refractive index of the interlayer dielectric layer 190. In the embodiment illustrated in FIG. 5, the light pipes 512 and 514 are depicted as being wide at the top and narrow at the bottom, however, the present disclosure is not limited thereto, the light pipes may be any suitable shape.

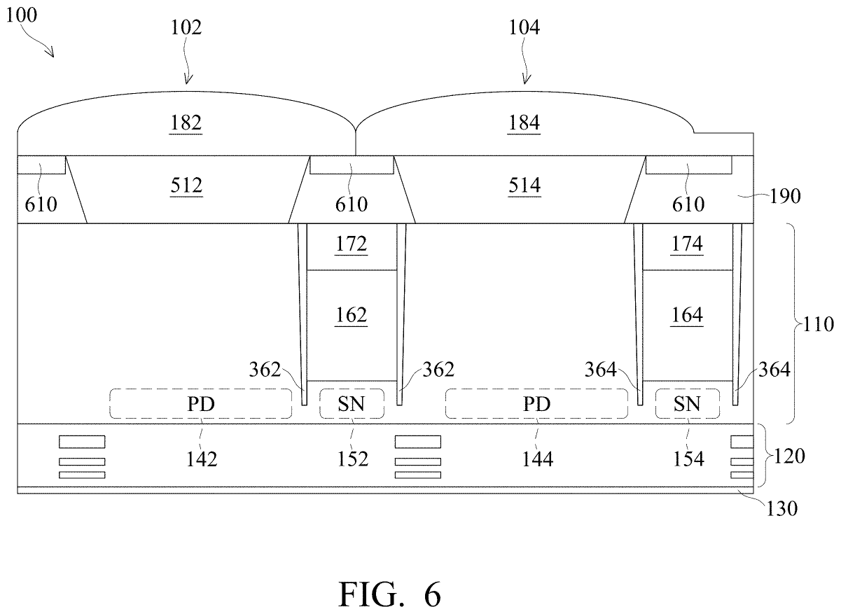

FIG. 6 illustrates a cross-sectional view of a portion of the image sensor, in accordance with some embodiments of the present disclosure. It should be noted that, since some features in FIG. 6 are the same as or similar to those in FIG. 5, the same reference signs are used for labeling these features herein.

Compared with FIG. 5, the semiconductor structure 100 in FIG. 6 further comprises light shielding structures 610 disposed between the light pipes. For example, one of the light shielding structures 610 is disposed between the light pipe 512 and the light pipe 514. The light shielding structures 610 may include the same or similar materials as the light shielding structure 172 (or the light shielding structure 174), and for the purpose of simplicity, it will not be repeated herein. The semiconductor structure 100 having the second set of light shielding structures (e.g. the light shielding structures 610) can more effectively prevent light from being incident to the storage nodes (e.g. the storage nodes 152 and 154). As a result, the optical crosstalk can be further reduced and the performance of the image sensor can be improved.

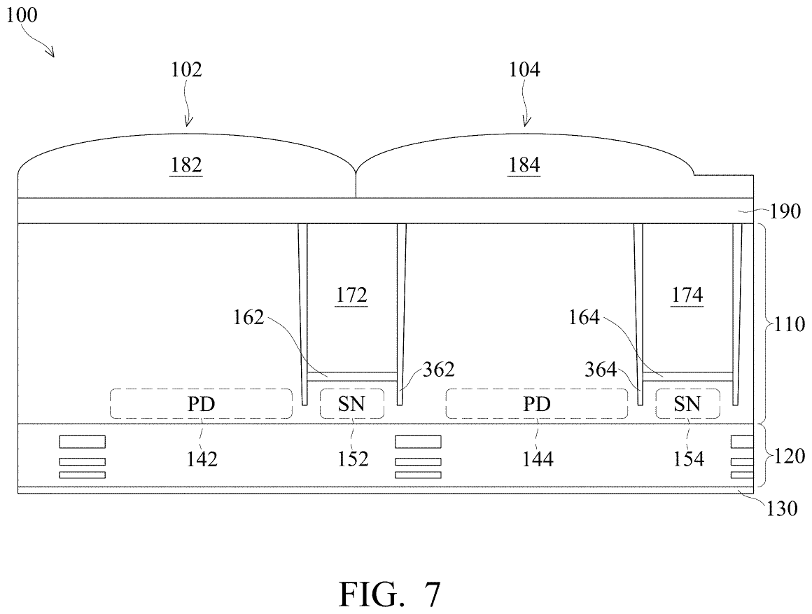

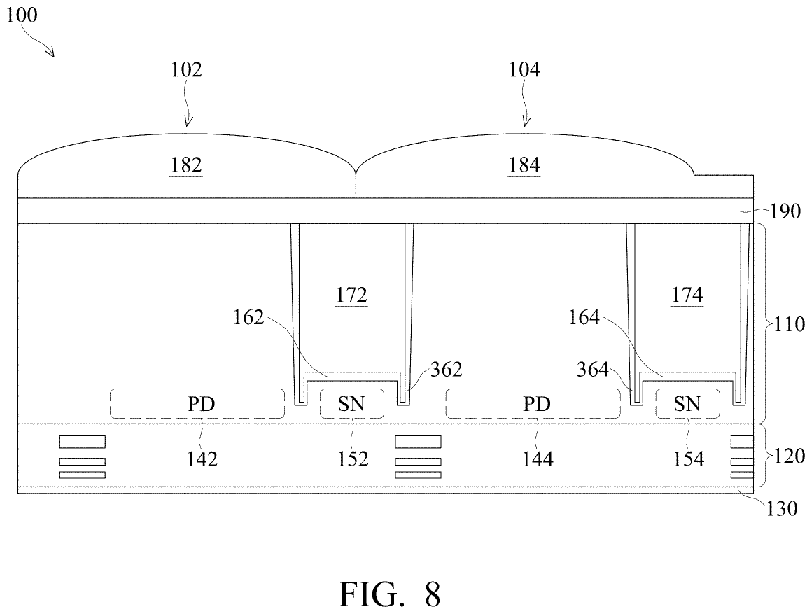

FIGS. 7 and 8 illustrate cross-sectional views of a portion of the image sensor, in accordance with some embodiments of the present disclosure. It should be noted that, since some features in FIGS. 7 and 8 are the same as or similar to those in FIG. 3, the same reference signs are used for labeling these features herein. As shown in FIGS. 7 and 8, the light shielding structures (e.g. the light shielding structures 172 and 174) have larger dimensions.

In the embodiment illustrated in FIG. 7, the light shielding structures 172 and 174 formed within the isolation structures 162 and 164 occupy most of the space of the isolation structures 162 and 164, for example, occupy 70% to 90% of the space. In the embodiment illustrated in FIG. 8, the light shielding structures 172 and 174 not only occupy most of the space of the isolation structures 162 and 164, but also extend into the isolation structures 362 and 364. Therefore, the light shielding structures 172 and 174 partially surround the storage nodes 152 and 154, respectively.

It should be noted that, the present disclosure is not limited to the embodiments described above. The embodiments shown in FIGS. 1 to 8 can be recombined with each other to produce new embodiments, and these new embodiments are all encompassed by the present disclosure. For example, different pixels may have different structures, such as different light shielding structure dimensions, different light shielding structure positions, and whether to have a second set of isolation structures (e.g. the isolation structures 362 and 364), and so on. Alternatively, one pixel can have both a color filter and a light pipe.

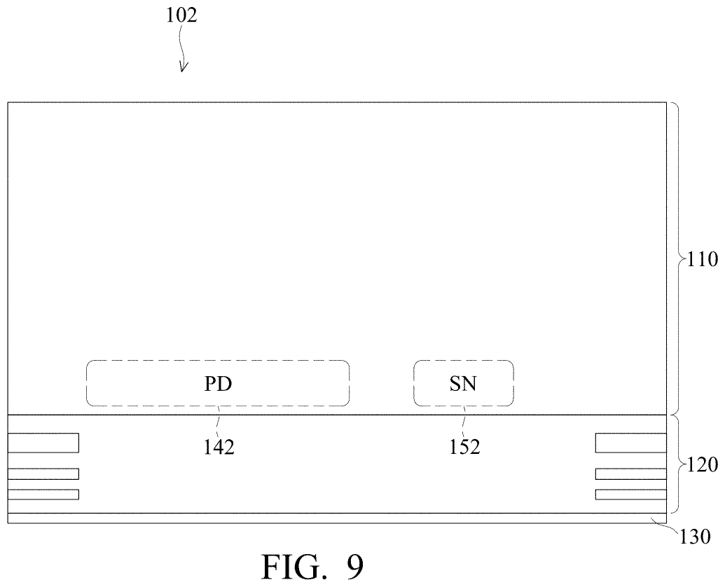

FIGS. 9 to 16 illustrate cross-sectional views of intermediate stages for forming a portion of the image sensor, in accordance with some embodiments of the present disclosure. For the purpose of simplicity, FIGS. 9 to 16 use the same reference signs as those in FIGS. 1 to 8, and illustrate the first pixel 102 only.

In FIG. 9, a semiconductor structure is provided. The semiconductor structure includes a substrate 110, an intermetal dielectric layer 120, a passivation layer 130, a photodiode 142, and a storage node 152. As described above, the substrate 110 and interlayer dielectric layer 120 may comprise interconnect structures having multiple metal layers and various elements, such as transfer gates, global transfer gates, reset transistors, source followers, floating diffusion elements, etc.

The various structures and the various elements described above can be formed by various semiconductor processes, such as epitaxy processes, photolithography processes, deposition processes, etching processes, doping processes, planarization processes, and the like. The planarization processes may include a chemical mechanical polishing (CMP) process. The doping processes may include an ion implantation process.

The epitaxy processes may include chemical vapor deposition (CVD), low-pressure CVD (LPCVD), low-temperature CVD (LTCVD), rapid thermal CVD (RTCVD), plasma enhanced CVD (PECVD), high density plasma CVD (HDPCVD), metal organic CVD (MOCVD), molecular beam epitaxy (MBE), liquid phase epitaxy (LPE), vapor phase epitaxy (VPE), atomic layer epitaxy (ALE), other suitable epitaxy processes, or combinations thereof.

The photolithography processes may include photoresist coating (e.g., spin-on coating), soft baking, mask aligning, exposure, post-exposure baking, developing the photoresist, rinsing, and drying (e.g., hard baking). Alternatively, the photolithography processes may be implemented or replaced by other suitable methods, such as maskless photolithography, electron-beam writing, and ion-beam writing. The etching processes may include dry etching, wet etching, reactive ion etching (RIE), and/or other suitable processes.

The deposition processes may include physical vapor deposition (PVD) process, CVD process, coating process, other suitable processes, or combinations thereof. The PVD process may include sputter process, evaporation process, and pulsed laser deposition process. The CVD process may include LPCVD, LTCVD, RTCVD. PECVD. HDPCVD, MOCVD, remote plasma CVD (RPCVD) process, atomic layer deposition (ALD) process, plating process, other suitable processes, and/or combinations thereof.

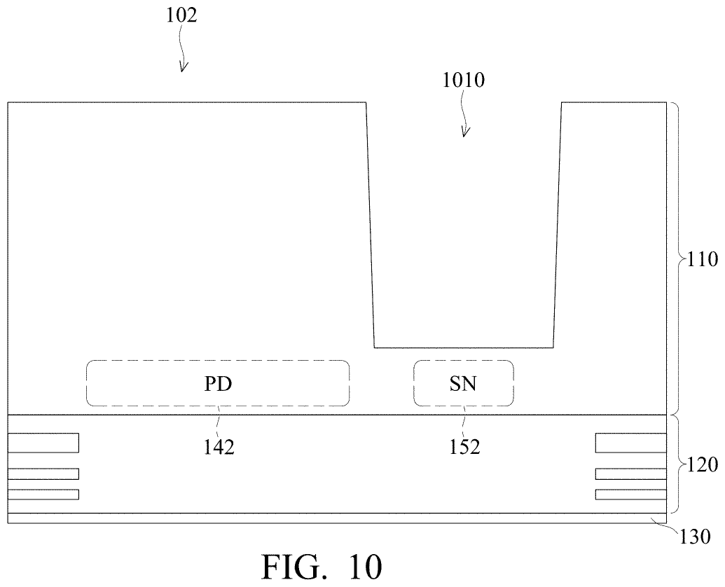

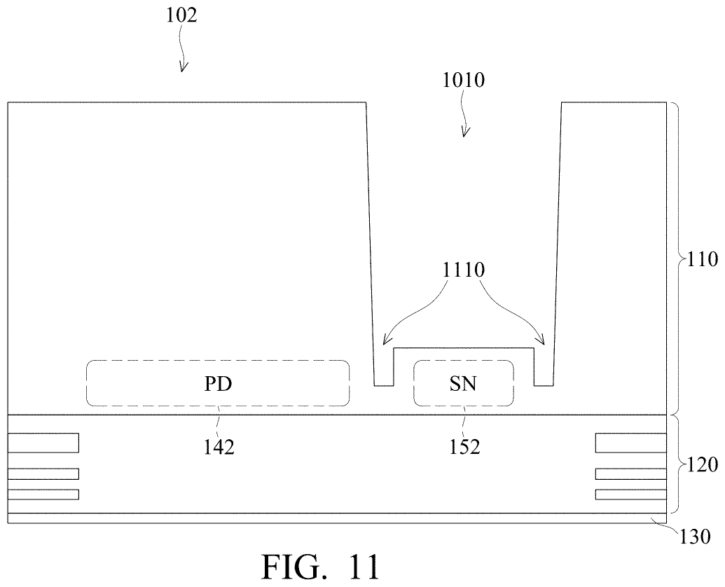

In FIG. 10, a trench 1010 is formed in the substrate 110 over the storage node 152. The trench 1010 may be formed in the substrate 110 by suitable photolithography processes and etching processes. In FIG. 11, a trench 1110 is further formed in the trench 1010, wherein the trench 1110 partially surrounds the storage node 152. The trench 1110 may be formed in the trench 1010 by suitable photolithography processes and etching processes.

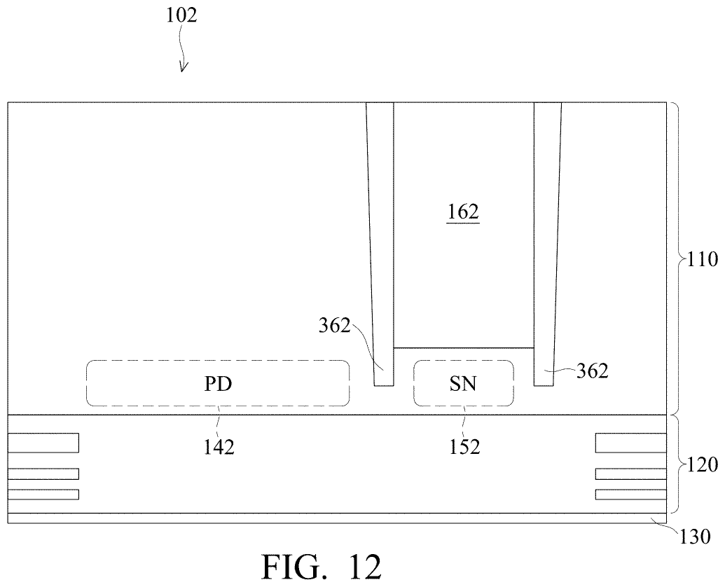

In FIG. 12, an isolation structure 162 and an isolation structure 362 are formed in the trench 1010 and the trench 1110. The isolation structure 162 and the isolation structure 362 may be formed by depositing material in the trench 1010 and the trench 1110 through suitable photolithography processes, etching process, and deposition processes, and then removing excess material by planarization processes. The materials of the isolation structure 162 and the isolation structure 362 have been described in the foregoing, and will not be repeated herein. In some embodiments, the isolation structure 362 is formed in the trench 1110 and on the sidewalls of the trench 1010, as shown in FIG. 12, the isolation structure 362 surrounds the isolation structure 162 and partially surrounds the storage node 152. In other embodiments, the isolation structure 362 is only formed in the trench 1110, so the isolation structure 362 only partially surrounds the storage node 152 and does not surround the isolation structure 162.

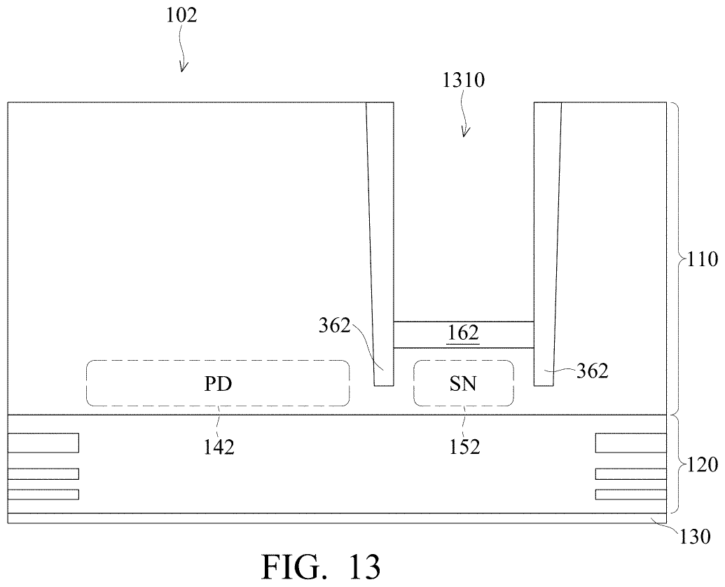

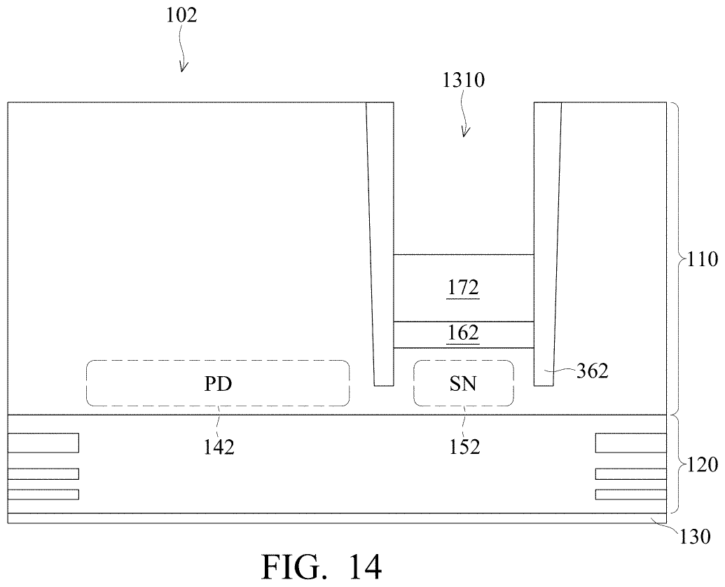

In FIG. 13, a trench 1310 is formed in the isolation structure 162 and/or the isolation structure 362. The trench 1310 may be formed in the isolation structure 162 and/or the isolation structure 362 by suitable photolithography processes and etching processes. In FIG. 14, a light shielding structure 172 is formed in the trench 1310. The light shielding structure 172 may be formed in the trench 1310 by suitable photolithography processes, etching processes, and deposition processes. The material of the light shielding structure 172 has been described in the foregoing, and will not be repeated herein.

The depth of the trench 1310 may be controlled by adjusting the etching processes to control the position of the light shielding structure 172, such as the different positions of the light shielding structure 172 shown in FIG. 1 and FIG. 2. In addition, the dimension of the light shielding structure 172 may be controlled by adjusting the deposition processes, for example, the different dimensions of the light shielding structure 172 shown in FIG. 3 and FIG. 7. Furthermore, the different shapes of the light shielding structure 172 may be controlled by adjusting the etching processes and the deposition processes, such as the different shapes of the light shielding structure 172 shown in FIG. 3, FIG. 7 and FIG. 8.

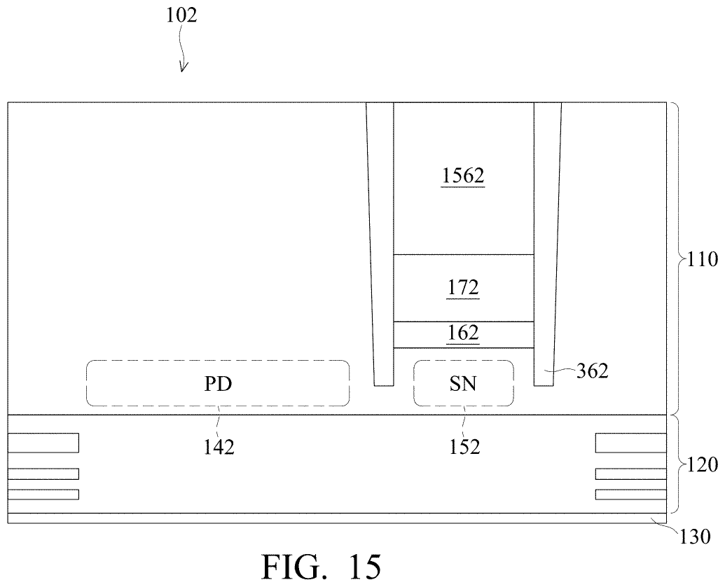

In FIG. 15, an isolation structure 1562 is formed in the remaining portion of the trench 1310. The isolation structure 1562 may be formed by depositing material in the remaining portion of the trench 1310 through suitable photolithography processes, etching processes, and deposition processes, and then removing excess material by planarization processes. The isolation structure 1562 may have the same or similar material as the isolation structure 162 and may serve as a portion of the isolation structure 162.

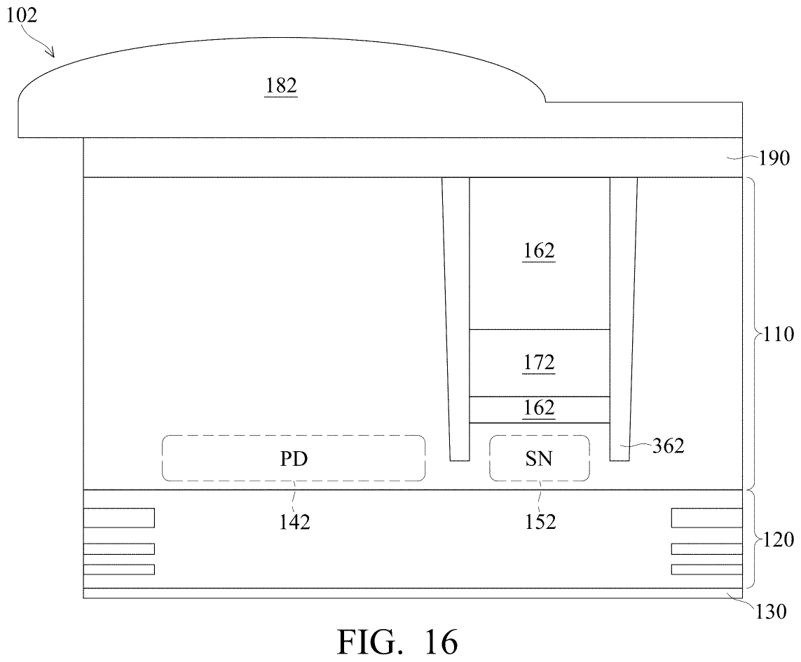

In FIG. 16, an interlayer dielectric layer 190 is formed over the second end of the substrate 110, and a lens structure 182 is formed over the interlayer dielectric layer 190. The interlayer dielectric layer 190 may be formed over the substrate 110 by suitable photolithography processes, etching processes, and deposition processes. The material of the interlayer dielectric layer 190 has been described in the foregoing, and will not be repeated herein. In FIG. 16, the isolation structure 1562 of FIG. 15 is regarded as a portion of the isolation structure 162.

A material layer of the lens structure may be formed over the interlayer dielectric layer 190 by deposition processes, casting, or other suitable methods, wherein the material of the lens structure may be quartz, gallium phosphide, calcium fluoride, silicon, other suitable materials, or combinations thereof. Then, the material layer may be patterned by photolithography processes and etching processes to form the lens structure 182. Alternatively, the lens structure 182 may be formed by laser writing, gray mask, screen printing, relief casting, photoresist reflow, micro injection molding, non-contact compression molding, hot embossing, other suitable methods, or combinations thereof.

It should be understood that, additional operations may be performed before, during, or after the operations shown in FIGS. 9 to 16. In addition, the order of the operations shown in FIGS. 9 to 16 may be changed, and some operations may be replaced or omitted. For example, the operations for forming the trench 1110 and forming the isolation structure 362 may be omitted to form the semiconductor structure as shown in FIGS. 1 and 2.

In addition, additional operations for forming color filters (e.g. the color filter 412), light pipes (e.g. the light pipe 512), and the second set of light shielding structures (e.g. the light shielding structure 610) may be performed to form the semiconductor structure as shown in FIGS. 4 and 5. Using any suitable lithography, etching, and deposition processes, the color filter 412 may be formed on the interlayer dielectric layer 190, and the light pipe 512 and the light shielding structure 610 may be formed in the interlayer dielectric layer 190. In addition, additional isolation structures, such as shallow trench isolation (STI) structures or deep trench isolation structures, can also be formed to separate different elements and/or different pixels.

The present disclosure provides a novel image sensor structure, including isolation structures and light-shielding structures disposed over storage nodes. The isolation structures can block the electrons excited by the photons incident to the substrate, such that the electrons cannot diffuse to the storage nodes. In this way, the electrical crosstalk of the image sensor can be reduced. On the other hand, the light-shielding structures can prevent photons from being directly incident to the storage nodes. In this way, the optical crosstalk of the image sensor can be reduced. As a result, the performance degradation caused by parasitic light sensitivity can be dramatically suppressed, and thus the performance of the image sensor can be improved.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor, comprising:
a substrate;
a photodiode, disposed in the substrate and close to a first end of the substrate;
a storage node, disposed in the substrate, adjacent to the photodiode, and close to the first end of the substrate;
a first isolation structure, disposed in the substrate and over the storage node;
a first light shielding structure, disposed in the first isolation structure;
an interlayer dielectric layer, disposed over a second end of the substrate, wherein the second end is opposite the first end; and
a lens structure, disposed over the interlayer dielectric layer.

2. The image sensor as claimed in claim 1, further comprising a color filter, disposed between the interlayer dielectric layer and the lens structure.

3. The image sensor as claimed in claim 1, further comprising a first light pipe, disposed in the interlayer dielectric layer, and between the lens structure and the substrate.

4. The image sensor as claimed in claim 3, further comprising a second light shielding structure, disposed in the interlayer dielectric layer, and between the first light pipe and a second light pipe adjacent to the first light pipe.

5. The image sensor as claimed in claim 1, further comprising a second isolation structure, disposed in the substrate, surrounding the first isolation structure, and partially surrounding the storage node.

6. The image sensor as claimed in claim 5, wherein the first light shielding structure extends into the second isolation structure, and partially surrounds the storage node.

7. The image sensor as claimed in claim 1, wherein the first light shielding structure within the first isolation structure is close to the second end of the substrate.

8. The image sensor as claimed in claim 1, further comprising a floating diffusion element, disposed in the substrate, adjacent to the storage node, and close to the first end of the substrate.

9. The image sensor as claimed in claim 8, further comprising:
an intermetal dielectric layer, disposed below the first end of the substrate; and
a passivation layer, disposed below the intermetal dielectric layer.

10. The image sensor as claimed in claim 1, wherein a center of the lens structure is aligned with a center of the photodiode.

11. A method for manufacturing an image sensor, comprising:
providing a semiconductor structure, wherein the semiconductor structure comprises a substrate and an intermetal dielectric layer below a first end of the substrate, and wherein the substrate comprises a photodiode close to the first end and a storage node close to the first end and adjacent to the photodiode;
forming a first trench in the substrate from a second end of the substrate, wherein the second end is opposite the first end, and wherein the first trench is over the storage node;
forming a first isolation structure in the first trench;
forming a second trench in the first isolation structure; and
forming a first light shielding structure in the second trench.

12. The method as claimed in claim 11, further comprising:
forming a third trench in the first trench, wherein the third trench partially surrounds the storage node; and
forming a second isolation structure in the third trench, wherein the second isolation structure partially surrounds the storage node.

13. The method as claimed in claim 11, further comprising:
after forming the first light shielding structure, forming a third isolation structure in a remaining portion of the second trench.

14. The method as claimed in claim 11, further comprising:
forming an interlayer dielectric layer over the second end of the substrate; and
forming a lens structure over the interlayer dielectric layer.

15. The method as claimed in claim 14, further comprising:
forming a color filter over the interlayer dielectric layer, wherein the color filter is between the interlayer dielectric layer and the lens structure.

16. The method as claimed in claim 14, further comprising:
forming a light pipe in the interlayer dielectric layer, wherein the light pipe is between the substrate and the lens structure.

17. The method as claimed in claim 16, further comprising:
forming a second light shielding structure in the interlayer dielectric layer, wherein the second light shielding structure is over the first light shielding structure and adjacent to the light pipe.
